(19) United States
(12) Patent Application Publication
(10) Pub. No.: US 2019/0118312 A1
(43) Pub. Date: Apr. 25, 2019

(54) SOLDER FLUX CONTAINING FLUORESCENT MICROCAPSULES AND METHOD TO VISUALIZE UNACTIVATED SOLDER FLUX

(71) Applicant: International Business Machines Corporation, Armonk, NY (US)

(72) Inventors: Jennifer I. BENNETT, Rochester, MN (US); Eric J. CAMPBELL, Rochester, MN (US); Sarah K. CZAPLEWSKI-CAMPBELL, Rochester, MN (US); Joseph KUCZYNSKI, North Port, FL (US)

(21) Appl. No.: 15/792,136

(22) Filed: Oct. 24, 2017

(51) Int. Cl. B23K 35/362; B23K 35/36; B23K 35/02; C09K 11/02; C09K 11/06; B01J 13/02; H05K 3/34

(52) U.S. Cl. CPC B23K 35/362; B23K 35/3612; B23K 35/0244; C09K 11/02; B23K 2201/42; B01J 13/02; H05K 3/3489; C09K 2211/1011; C09K 2211/1044; C09K 11/06

(57) ABSTRACT

A multi-compartment microcapsule quenches fluorophores in response to a stimulus. In some embodiments, the multi-compartment microcapsules have first and second compartments separated by an isolating structure adapted to change in permeability in response to the stimulus, wherein the first and second compartments contain reactants that come in contact and react to quench a fluorescent compound when the isolating structure changes in permeability.

### FIELD OF THE DISCLOSURE

The disclosure herein relates in general to the field of materials science, and more specifically, to multi-compartment microcapsules that cease to produce light and/or produce light when subjected to a stimulus.

### BACKGROUND

Embodiments described herein relate to materials and methods of making multi-compartment capsules that cease to fluoresce when subjected to a stimulus. In some embodiments, a method is provided. The method can be used to determine whether a region of no-clean flux reaches a desired temperature, for example an inactivation temperature, during solder reflow or solder rework process.

Flux is a necessary component of printed circuit board (PCB) assemblies because flux improves and allows wetting of the solder to a pad on the PCB. However, flux residues are known to cause chemical corrosion, electro-chemical corrosion, and encourage electrochemical migration because the residues are acidic and hygroscopic, and contain free ions. No-clean fluxes pose an even greater risk of corrosion because the flux residues aren't cleaned off after soldering or reflow. However, no-clean fluxes become inert if they become inactivated, which entails heating the solder flux up to an elevated temperature for a period of time during the solder reflow process so that the volatile solvents present in the flux are evaporated out of the flux. Once activated, the flux becomes relatively inert and traps in the corrosive agents. Therefore, a method that can determine whether a no-clean flux has reached the desired temperature for full activation is needed.

### SUMMARY

Embodiments described herein relate to materials and methods of making multi-compartment capsules cease to fluoresce when subjected to a stimulus. More specifically, embodiments herein relate to methods to determine whether a region of no-clean flux reaches a desired temperature during solder reflow or solder rework process. The methods utilize fluorescent molecules to indicate flux activity.

According to an embodiment, a multi-compartment microcapsule is provided. The multi-compartment microcapsule includes a first compartment containing a fluorescent reactant; a second compartment containing a reagent reactive with the fluorescent reactant; and an isolating structure separating first and second compartments from each other and adapted to change in permeability in response to a stimulus, wherein the fluorescent reactant and reagent come in contact and react to decrease fluorescence when the isolating structure changes in permeability.

In another embodiment, a method of making a solder flux containing multi-compartment microcapsules is provided. The method includes preparing a microparticle containing a fluorescent reactant immobilized in a first sacrificial colloidal template; coating a first polymer on a surface of the microparticle to form a polymer-coated microparticle; preparing a ball-in-ball microparticle containing a reagent reactive with the fluorescent reactant, the reagent immobilized in a second sacrificial colloidal template, wherein the ball-in-ball microcapsule incorporates the polymer-coated microparticle; coating a second polymer on a surface of the ball-in-ball microparticle to form a polymer-coated ball-in-ball microparticle; and extracting the first and second colloidal templates from the polymer-coated ball-in-ball microparticle to form a shell-in-shell microcapsule having an inner shell and an outer shell, wherein the inner shell comprises the first polymer and contains the fluorescent reactant, wherein the outer shell corresponds to the second polymer and contains the quenching reagent, and wherein the fluorescent reactant and reagent are capable of reacting together to quench or partially quench fluorescence of the fluorescent reactant.

In another embodiment, a method of detecting a temperature threshold is provided. The method includes mixing a first material and temperature dependent fluorescent microcapsules to form a mixture; applying the mixture to one or more parts to be heated; exposing the mixture and one or more parts to be heated to a first temperature range; and detecting fluorescence of the mixture after exposure to a first temperature range.

Features and other benefits that characterize embodiments are set forth in the claims annexed hereto and forming a further part hereof. However, for a better understanding of the embodiments, and of the advantages and objectives attained through their use, reference should be made to the Drawings and to the accompanying descriptive matter.

### BRIEF DESCRIPTION OF THE SEVERAL VIEWS OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, for the disclosure may admit to other equally effective embodiments.

FIG. 1A depicts a multi-compartment microcapsule having a shell-in-shell architecture with an inner shell contained within an outer shell, wherein the inner shell is adapted to change in permeability in response to a temperature change according to some embodiments.

FIG. 1B depicts a multi-compartment microcapsule having an inner barrier to form compartments, wherein the inner barrier is adapted to change in permeability in response to a temperature change according to some embodiments.

FIG. 2A illustrates a multi-compartment microcapsule containing reactants according to some embodiments.

FIG. 2B illustrates a multi-compartment microcapsule in which the capsule wall of the inner microcapsule changes in permeability according to some embodiments.

FIG. 2C illustrates a multi-compartment microcapsule in which a first reactant is dispersed within a second reactant according to some embodiments.

FIG. 2D illustrates a multi-compartment microcapsule in which the reactants within the microcapsule have quenched, or partially quenched the fluorescence of the fluorophore according to some embodiments.

FIG. 3 is a flow diagram illustrating a method of producing a multi-compartment microcapsule having a shell-in-shell architecture with an inner shell contained within an outer shell, wherein the inner shell is adapted to change in permeability in response to a temperature change in some embodiments.

FIG. 4 is a flow diagram illustrating a general method of detecting a temperature threshold according to some embodiments.

FIG. 5 is a flow diagram illustrating a method to detect inactivated solder flux according to some embodiments.

### DETAILED DESCRIPTION

Embodiments described herein relate to materials and methods of making multi-compartment capsules that cease to fluoresce when subjected to a stimulus. More specifically, embodiments herein relate to methods to determine whether a region of no-clean flux reaches a desired temperature, for example an inactivation temperature, during solder reflow or solder rework process.

In some embodiments, the methods utilize fluorescent molecules to indicate flux activity. The fluorophore system will quench or partially quench at a temperature indicative of the temperature needed to get sufficient flux inactivation. Typically, sufficient flux inactivation can be achieved by baking at about 85° C. to about 105° C. for about 0 to about 2 hours to drive off residual weak organic acids and to render the flux inert. Thus, the temperature at which the inner wall/shell breaks needs to be similar to the temperature necessary for flux inactivation, i.e., a temperature or temperature range of about 85° C. to about 105° C. Depending on the application of use, sufficient solder inactivation may be 50% or more decrease in fluorescence as measured by a fluorimeter, including no measurable fluorescence after soldering.

As used herein, the term “inactivated” is used to refer to solvent driven out of flux during solder reflow. As used herein, quenching refers to processes that decrease the fluorescence intensity of a given substance.

As used herein, the terms “change(s) in permeability” and “changing in permeability” includes rupturing, melting, decomposing, swelling, and changing shape.

As used herein, the terms “microcapsule” and “microparticle” are used to refer to capsules and particles that are in a range of about 10 microns to about 1000 microns in diameter. However, it will be appreciated that the following disclosure may be applied to capsules having a smaller size (also referred to as “nanocapsules” or “nanoparticles”).

The multi-compartment microcapsules described herein include two or more compartments containing reactants that come in contact and react to render fluorescent molecules in one or more compartments non-fluorescent when an isolating structure changes permeability in response to a stimulus. Aspects of the disclosure include fluorescent microcapsules and methods of producing a fluorescent multi-compartment microcapsule. Other aspects include solder fluxes containing fluorescent microcapsules, and methods of making a solder flux containing such microcapsules. Other aspects include methods of making a solder contact using solder flux containing fluorescent microcapsules.

The multi-compartment microcapsules fluoresce. When subjected to a stimulus (e.g., heat), the multi-compartment microcapsules are rendered non-fluorescent.

Fluorescent molecules encapsulated in shell in shell microcapsules are incorporated into the flux material. When the temperature of the flux and the microcapsules reaches a desired temperature sufficient to inactivate the flux (i.e., a temperature or temperature range of about 85° C. to about 105° C.), the fluorescent molecules undergo a chemical reaction to render them non-fluorescent. This is achieved by tailoring the inner shell material to melt, decompose, or change shape at a desired activation temperature. When the inner shell wall changes in permeability, the fluorescent molecules are exposed to a second reactant and undergo the chemical reaction to convert them from fluorescent molecules to non-fluorescent molecules.

Upon inspection of the flux coated component after solder reflow, unactivated flux can be identified using a wavelength of light needed to achieve fluorescence from the encapsulated molecules. If areas of the component/board fluoresce, then the user will know that unactivated flux is present on the component and that area should be reheated to drive off the remaining solvent carrier.

The embodiments described herein are particularly useful in the rework process since the whole board may not undergo reflow and heat may only be applied to selected areas. Therefore, some solder flux could be applied/spread to unintended areas and not be fully inactivated as those areas may not be exposed to heat.

In some embodiments, the multi-compartment microcapsules have first and second compartments separated by an isolating structure adapted to change in permeability in response to the stimulus, wherein the first and second compartments contain reactants that come in contact and quench, or partially quench, when the isolating structure changes in permeability. In some embodiments, the multi-compartment microcapsules are shell-in-shell microcapsules each having an inner shell contained within an outer shell, wherein the inner shell defines the isolating structure and the outer shell does not allow the fluorescence chemistry to escape the microcapsule upon change in permeability of the inner shell.

Multi-compartment microcapsules are known in the art to be formed in a variety of structural configurations (e.g., concentric, pericentric, innercentric, or acentric). Multi-compartment microcapsules include at least two compartments that are separated from each other. The compartments within a multi-compartment microcapsule may contain various chemical elements or compounds. Multi-compartment microcapsules may be produced using techniques well known to those skilled in the art.

In the embodiments that follow, exemplary non-limiting fluorophores and quenchers are used. These exemplary fluorescent reactants may be used in the fluorescent shell in shell microcapsules. These exemplary reactants are set forth for purposes of illustration, not limitation. One skilled in the art will appreciate that a reaction consistent with the spirit of the present disclosure may be used in other contexts. Quenching, herein, refers to processes that decrease the fluorescence intensity of a given substance. Common quenchers include molecular oxygen, iodide ions, chloride ions, acrylamide, methylene iodide, and nitromethane, among others.

In accordance with some embodiments of the present disclosure, a fluorescent microcapsule may utilize a multi-compartment microcapsule containing a quencher, which may be methylene iodide (CH₂I₂) (also known as diiodomethane), or any other suitable quencher, and pyrene (1), or any other suitable fluorophore. Fused diimides such as the perylene diimides 2-7, wherein R¹ and R² are each independently hydrogen or C₁ to C₄₀ branched or unbranched hydrocarbyl, C₁ to C₄₀ substituted or unsubstituted hydrocarbyl, C₁ to C₄₀ saturated or unsaturated hydrocarbyl, unsubstituted aryl, substituted aryl, unsubstituted heteroaryl, or substituted heteroaryl.

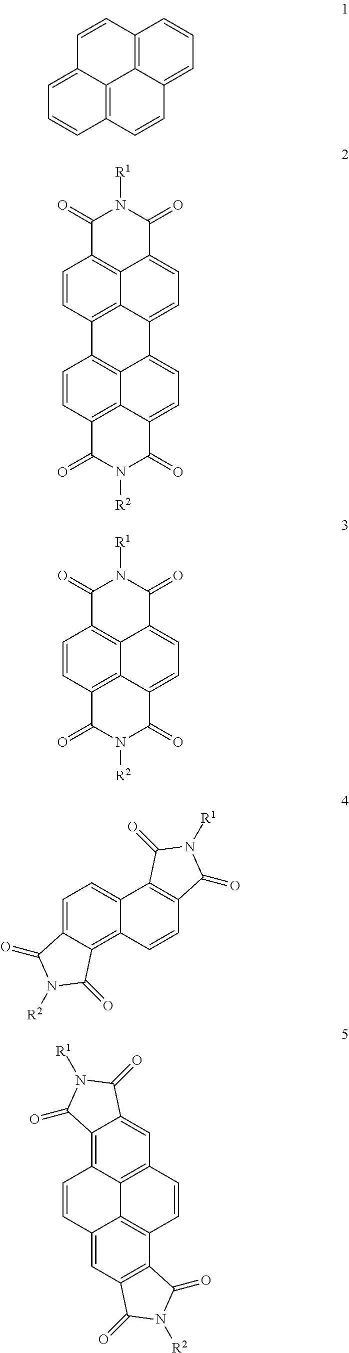

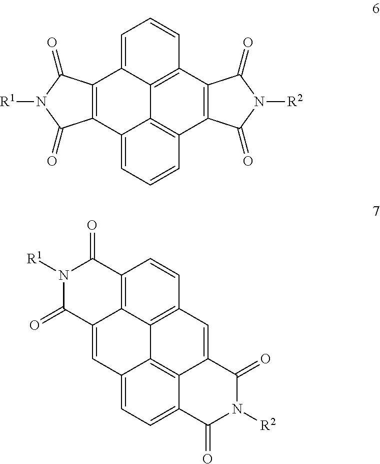

One skilled in the art will appreciate that other fluorophores may be used. Suitable fluorophores include xanthenes (including fluorescein, rhodamine, eosin, and sulforhodamine 101 acid chloride), cyanines (including cyanine, indocarbocyanine, oxacarbocyanine, thiacarbocyanine, and merocyanine), squaraines (including Seta, including those available from Seta Biomedical such as SeTau-647, and Square dyes), napthalenes (including dansyl and prodan derivatives), coumarins, quinines, oxadiazoles (including pyridyloxazole, nitrobenzoxadiazole and benzoxadiazole), anthracenes (including anthraquinones), pyrenes (including Cascade Blue from ThermoFisher), oxazines (including nile red (9-diethylamino-5-benzo[α]phenoxazinone), nile blue (9-(diethylamino)benzo[a]phenoxazin-5-ylidene]azanium; sulfate), and cresyl violet ((9-dimethylamino-10-methyl-benzo[a]phenoxazin-5-ylidene)ammonium chloride)), acridines (including proflavin, acridine orange, and acridine yellow), arylmethines (including auramine, crystal violet, and malachite green), tetrapyrroles (including porphin, phthalocyanine, and bilirubin), perylene diimides, and proteins. These fluorophores are readily synthesized from commercially available starting materials or can be purchased.

Solvents for the fluorophores and quenchers include solvents that are compatible with heating the solder flux. Such solvents include polar protic solvents (such as aqueous solutions and ethanol), polar aprotic solvents (such as N,N-dimethylformamide (DMF), dimethyl sulfoxide (DMSO), and propylene carbonate), hydrocarbon solvents (such as benzene and toluene), and solvent mixtures thereof. Other solvents include gamma butyrolactone, dimethyl imidazolidinone, and the oligoethyleneglycols such as tetraethylene glycol (BP=314° C.).

In addition, many solvents and chemicals (for example, benzene) are known to fluoresce in the ultraviolet wavelengths. Upon interaction with a quenching reactant, a concomitant decrease in fluorescence spectra can be detected using a fluorimeter.

The change in fluorescence will not occur until the inner shell wall of the shell in shell microcapsule changes in permeability. The inner shell wall material is designed to decompose, melt, shape change, among other things, at a given temperature. This temperature or temperature range can be in the range of about 85° C. to about 105° C.

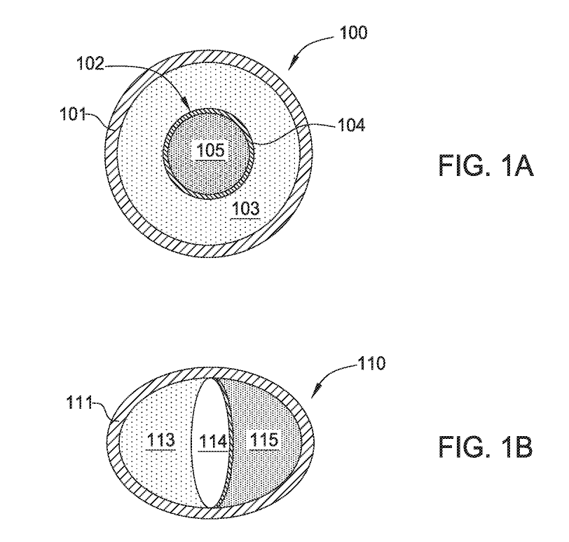

FIG. 1A depicts a multi-compartment microcapsule 100 having a shell-in-shell architecture with an inner shell contained within an outer shell, wherein the inner shell is adapted to change in permeability at a particular temperature or in a particular temperature range according to some embodiments of the present disclosure. In FIG. 1A, the multi-compartment microcapsule 100 is illustrated in a cutaway view. The multi-compartment microcapsule 100 has an outer wall 101 (also referred to herein as the “outer shell” 101 of the multi-compartment microcapsule 100) and contains an inner microcapsule 102 and a first reactant 103. The inner microcapsule 102 has a capsule wall 104 (also referred to herein as the “inner shell” 104 of the multi-compartment microcapsule 100) and contains a second reactant 105. The first reactant 103 within the multi-compartment microcapsule 100 may surround the inner microcapsule 102, and the first reactant 103 may be prevented from contacting the second reactant 105 by the capsule wall 104 of the inner microcapsule 102.

The capsule wall 104 of the inner microcapsule 102 may be formed to change in permeability at a particular temperature or in a particular temperature range and the outer wall 101 of the microcapsule 100 may be formed so as not to change in permeability at that particular temperature or in that particular temperature range. Changing the permeability of the capsule wall 104 of the inner microcapsule 102 may allow the second reactant 105 to contact the first reactant 103 and the reactants may then chemically or physically react to render the microcapsules non-fluorescent. Until such contact between the first and second reactants 103 and 105 occurs, at least one of the reactants 103 and 105 will fluoresce. In this way, a change in permeability of the inner microcapsule 102, and therefore indication of a target temperature exposure, can be detected.

FIG. 1B depicts a multi-compartment microcapsule 110 having an inner barrier that defines compartments, wherein the inner barrier is adapted to change in permeability at a particular temperature or in a particular temperature range according to some embodiments of the present disclosure. In FIG. 1B, the multi-compartment microcapsule 110 is illustrated in a cutaway view. The multi-compartment microcapsule 110 has an outer wall 111 and contains a first reactant 113 and a second reactant 115. An inner barrier 114, which may be a membrane, within the multi-compartment microcapsule 110 may prevent the first reactant 113 and the second reactant 115 from coming into contact. The inner barrier 114 may be any form of a physical barrier that forms two or more compartments within the microcapsule 110.

Multi-compartment microcapsule 110 may be made using a method of partially shielding a lower part of the particles/capsules incorporated in soft films. Under this approach, a first plurality of particles or capsules are deposited onto a film, for example a film of hyaluronic acid/L-lysine copolymer, leaving the upper part of the particle non-protected. In a subsequent step, a second plurality of particles or capsules, each of which is typically smaller than the particles of the first plurality, are adsorbed onto the non-protected part of the embedded particles of the first plurality. Extraction of the embedded particles is done by exposing the particles embedded in the film to an appropriate solvent. The solvent loosens the interaction between the films and capsules/particles, thus allowing the latter to detach and be collected. Suitable solvents include water. Other films and solvents known to those skilled in the art can be utilized.

The inner barrier 114 may be formed to change in permeability at a particular temperature or in a particular temperature range and the outer wall 111 of the multi-compartment microcapsule 110 may be formed so as not to change in permeability at that temperature or in that particular temperature range. A change in permeability of the inner barrier 114 may allow the first reactant 113 to contact the second reactant 115 and the reactants may then chemically react.

In accordance with some embodiments, the temperature applied to a fluorescent microcapsule may be within the range typical of that applied in the manufacture of circuit boards, adhesives, polymer, thermal interface materials, or any physical or chemical process in which microcapsules can be incorporated and which depends on achieving a certain temperature. For example, an adhesive that needs a certain temperature to adhere properly, or a polymer mixing or compounding process that needs to achieve a certain temperature.

In accordance with some embodiments, the inner capsule wall 104 (of the multi-compartment microcapsule 100 shown in FIG. 1A), or an inner barrier 114 (of the multi-compartment microcapsule 110 shown in FIG. 1B), may change in permeability at a temperature no greater than the lower bound of this range of temperatures. The outer wall 101 (of the multi-compartment microcapsule 100 shown in FIG. 1A), or the outer wall 111 (of the multi-compartment microcapsule 110 shown in FIG. 1B), may sustain, without a change in permeability, a temperature no less than the upper bound of this range of temperatures.

Other embodiments may utilize more than two reactants. The multi-compartment microcapsule 100 of FIG. 1A may contain a plurality of inner microcapsules, such as 102, and the inner microcapsules may themselves contain other, inner microcapsules and/or reactants. The various microcapsules may contain reactants and may change in permeability under a temperature change (i.e., a change to a particular temperature or to a range of temperatures) to allow the reactants to come into contact. Similarly, the multi-compartment microcapsule 110 of FIG. 1B may contain a plurality of compartments formed by a plurality of membranes or barriers, such as 114, and the compartments may in turn contain one or more membranes or barriers, or may contain microcapsules. The inner shells and outer shells may contain multiple chemicals, compounds, particles, and the like. The various membranes or barriers may change in permeability under temperature changes or ranges of temperature changes to allow the reactants to come into contact.

For example, using specific equivalencies in various microcapsules such that microcapsule A containing quenching reactant X changes in permeability at temperature 1, providing for example 0.5 equivalent of quenching reactant and leading to 50% reduction in fluorescence at temperature 1. Then at temperature 2, microcapsule B containing quenching reactant Y changes in permeability to provide 100% quenching of the fluorescence. In this example, with one fluorophore, you can determine two temperature thresholds. Such methods can be used to differentiate several temperatures.

The capsule walls of the inner microcapsule may be formed with one or more heat-sensitive polymers to change in permeability at a particular temperature or in a particular temperature range, and the outer wall of the microcapsule may be formed so as to not change in permeability at that particular temperature or in that particular temperature range. A change in permeability of the capsule wall of the inner microcapsule may allow the second reactant to contact the first reactant and the reactants may then chemically or physically react.

For aqueous systems, heat-sensitive polymers for the capsule wall of the inner microcapsule can be a made of a polymeric material that has a melting point, decomposition point, or shape change point in the desired temperature ranges compatible with aqueous systems. For such applications, the outer shell should be thermally stable at the desired temperature range. The polymer of the capsule wall of the inner microcapsule may be polyamides, polyimides, polyesters, urea-formaldehydes, among others. Alternatively, the solvent inside the inner capsule can be tailored to change the permeability of the capsule wall of the inner microcapsule at lower temperatures due to volatilization below 100° C.

For example, if it is desired for the capsule wall of the inner microcapsule to change in permeability at a temperature or temperature range of about 85° C. to about 105° C., polymers that melt in that temperature range, such as polycaprolactone and isotactic polypropylene oxide or mixtures of various polymers, can be used. However, different applications may require different polymers with the appropriate melting point. The melting point of polymers can be tailored for the specific application. Another example of a capsule wall of the inner microcapsule is N-Isopropylacrylamide (NIPAAm) which contracts upon heating to initiate thermal release because it undergoes a reversible lower critical solution temperature phase transition. The temperature at which the phase transition occurs can be altered by tailoring the polymer structure. NIPAAm microcapsule shells can also change in permeability from increased internal pressure upon contraction of the shell due to temperature increase. Other polymers that may be used include low density polyethylene.

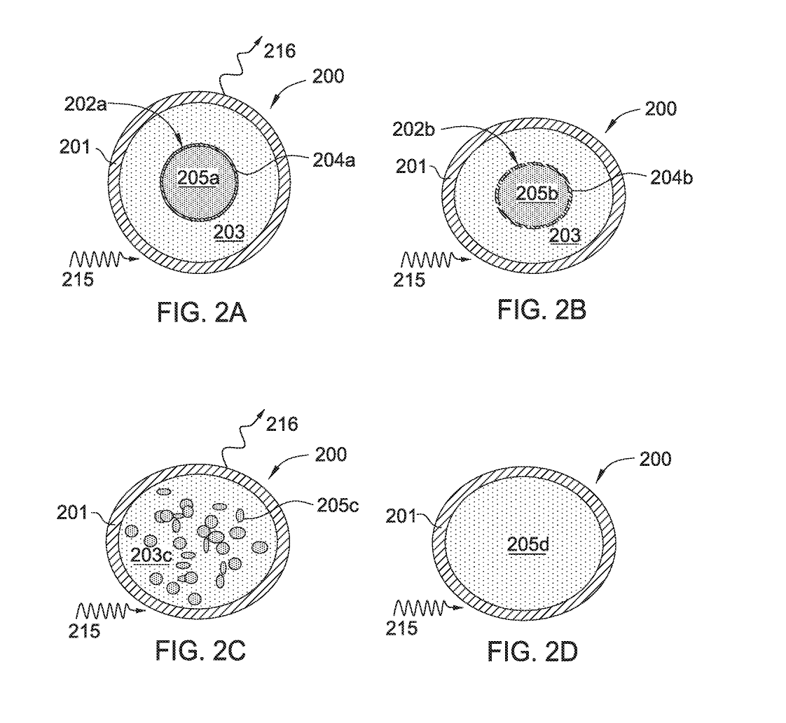

FIG. 2A, FIG. 2B, FIG. 2C, and FIG. 2D illustrate configurations of a multi-compartment microcapsule under a temperature change, and the temperature change causing the reactants within the microcapsule to mix, according to some embodiments of the present disclosure. FIG. 2A illustrates a first microcapsule containing reactants and an inner microcapsule. FIG. 2B illustrates the first microcapsule of FIG. 2A in which the inner microcapsule wall changes in permeability and the fluorophore is quenched, or partially quenched. FIG. 2C illustrates the first microcapsule of FIG. 2B in which a reactant contained in the inner microcapsule is dispersed within a reactant initially surrounding the inner microcapsule. FIG. 2D illustrates the first microcapsule of FIG. 2C in which the fluorophore is quenched, or partially quenched.

In more detail, FIG. 2A illustrates a microcapsule 200 formed to have a structure similar to that of the multi-compartment microcapsule 100 of FIG. 1A. Microcapsule 200 may have an outer wall 201 and may contain a first reactant 203 and an inner capsule 202a. The inner capsule 202a may have an outer capsule wall 204a and may contain a second reactant 205a. A temperature change may be applied to the multi-compartment microcapsule 200, which may cause the capsule wall 204a of an inner microcapsule 202a to change in permeability. Prior to the inner shell changing in permeability (as shown, for example, in FIG. 2B), the fluorescent molecules are able to fluoresce a wavelength of light 216 (for example a visible wavelength) when an ultraviolet (UV) light source 215 shines on it.

FIG. 2B illustrates a second configuration of microcapsule 200 in which the capsule wall 204b of the inner microcapsule 202b may change in permeability under a temperature change or range of temperature changes of the microcapsule 200, indicated by the broken line of the capsule wall 204b. After the inner shell wall breaks down (i.e., via melting, decomposing, changing shape), the fluorescent molecules are rendered non-fluorescent due to the chemical reaction between the two reactants. The applied light 215 passes through the microcapsule, and no fluorescence is emitted (for example, fluorescence in the visible spectrum) from the microcapsules when a UV light source 215 shines on it.

FIG. 2C illustrates a third configuration of microcapsule 200 in which the second reactant 205c may become dispersed within the first reactant 203c, in response to the inner microcapsule 202b having changed in permeability. The dispersion of the second reactant 205c within the first reactant 203c may cause them to react. Prior to the inner shell changing in permeability, the fluorescent molecules are able to fluoresce a wavelength of light 216 when an ultraviolet (UV) light source 215 shines on it.

FIG. 2D illustrates a fourth configuration of microcapsule 200 in which the reactants 203c and 205c may have come into contact and may have reacted. The fourth configuration of the microcapsule 200 may contain the product 205d of the reaction of 203c and 205c and the outer wall 201 may contain the reaction product 205d so as to prevent the reaction product from contacting a material in which microcapsule 200 may be itself dispersed. The reactants 203c and 205c may have reacted to quench, or partially quench, the fluorescence 216. After the inner shell wall breaks down (i.e., via melting, decomposing, changing shape), the fluorescent molecules have quenched or partially quenched due to the chemical reaction between the two reactants. The applied light 215 passes through the microcapsule, and no visible light is emitted (no fluorescence) from the microcapsules when a UV light source 215 shines on it.

In some embodiments, the multi-compartment microcapsule has a particle size in the range of about 0.5 to about 200 microns. In some embodiments, a multi-compartment microcapsule may have a diameter of less than about 5.0 microns, or a multi-compartment microcapsule may have a smaller diameter of less than about 2.0 microns. The particle size of the multi-compartment microcapsule can be smaller or larger based on the requirements of the encapsulating or the application.

A structure similar to multi-compartment microcapsule 110 of FIG. 1B, including the various embodiments thereof, may operate similarly to the microcapsule 200 of FIG. 2A through FIG. 2D to change the permeability of the inner barrier 114, which may be a membrane, mix the reactants 113 and 115, and quench, or partially quench, the fluorescence 216. It would be further apparent to one of ordinary skill in that art that a fluorescence-quenching reaction may be produced by more than two reactants, and that more than two reactants within a capsule may be isolated by more than one inner capsule or inner barrier, or more than one of any other form of barrier isolating the reactants within the capsule. A variety of reactants may be substituted to produce the quenching reaction, or a variety of reaction rates and total fluorescence quenched, in accordance with some embodiments of the present disclosure.

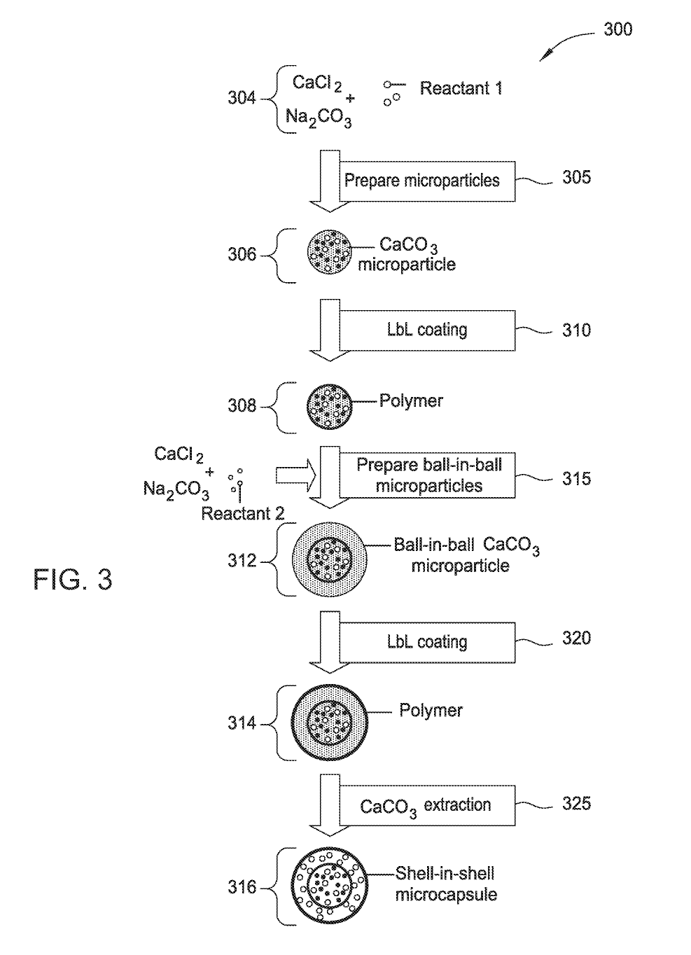

FIG. 3 is a flow diagram illustrating a method 300 of producing a multi-compartment fluorescent microcapsule having a shell-in-shell architecture with an inner shell contained within an outer shell, wherein the inner shell is adapted to change in permeability in response to a temperature change or range of temperature changes according to some embodiments of the present disclosure. In the method 300, the operations discussed below (operations 305, 310, 315, 320, and 325) are performed. Although these operations are described in preferred particular order, it should be understood that some of the operations may occur simultaneously or at other times relative to others. Moreover, those skilled in the art will appreciate that one or more operations may be omitted.

The microparticle system described in method 300 is based on CaCO₃ microparticles that are hardened by formation of a polyelectrolyte multilayer around the CaCO₃ microparticles.

In method 300, magnetic nanoparticles are used in operation 305 for incorporation into the “inner core” CaCO₃ microparticles (shown at stage 306) and, optionally, in operation 310 for incorporation into the “inner shell” polyelectrolyte multilayer (i.e., the “Polymer” shown at stage 308). Magnetic nanoparticles are incorporated into the “inner core” CaCO₃ microparticles for the purpose of subsequently magnetically isolating the product prepared in operation 315 (i.e., ball-in-ball CaCO₃ microparticles) from a coproduct (i.e., single core CaCO₃ microparticles). Another technique that can be used instead of magnetic nanoparticles is nanoscale interfacial complexation in emulsion (NICE).

In each of the stages 304, 306, 308, 312, 314, 316, the structure is shown in a cross-sectional side view. Referring to FIG. 3, and according to an embodiment, the shell-in-shell microcapsules can be made using a variety of fluorophores and quenchers (Reactant 1 and Reactant 2). For example, Reactant 1 may be pyrene, and Reactant 2 may be a quencher such as methylene iodide. Alternately, Reactant 1 may be a perylene diimide. Once the inner shell changes in permeability, the reactants mix and the fluorescence is quenched, or partially quenched. One skilled in the art will understand that a variety of fluorophores and quenchers can be used. Both Reactant 1 and Reactant 2 may comprise one or more chemicals, solvents, particles, and combinations thereof.

The method 300 begins by preparing spherical calcium carbonate microparticles in which Reactant 1 (for example, a fluorophore) is immobilized by coprecipitation (operation 305). For example, 1 M CaCl₂ (0.615 mL), 1 M Na₂CO₃ (0.615 mL), Reactant 1 (mg quantities), and deionized water (2.450 mL) may be rapidly mixed and thoroughly agitated on a magnetic stirrer for about 20 seconds at about room temperature. After the agitation, the precipitate may be separated from the supernatant by centrifugation and washed three times with water. One of the resulting CaCO₃ microparticles is shown at stage 306. Suitable solvents for the fluorophore during operation 305 include benzene, dimethylformamide (DMF), ethanol (EtOH), propylene carbonate, among others. An amount of solvent for the fluorophore is empirically determined by the amount of fluorophore used, for example, enough to at least partially solubilize the fluorophore.

The diameter of the CaCO₃ microparticles produced with a reaction time of about 20 seconds is about 4 μm to about 6 μm. Smaller CaCO₃ microparticles are produced if the reaction time is reduced from about 20 seconds to about several seconds.

In this example, the fabrication of polyelectrolyte capsules is based on the layer-by-layer (LbL) self-assembly of polyelectrolyte thin films. Such polyelectrolyte capsules are fabricated by the consecutive adsorption of alternating layer of positively and negatively charged polyelectrolytes onto sacrificial colloidal templates. Calcium carbonate is but one example of a sacrificial colloidal template. One skilled in the art will appreciate that other templates may be used in lieu of, or in addition to, calcium carbonate. For example, in accordance with other embodiments of the present disclosure, polyelectrolyte capsules may be templated on melamine formaldehyde or silica rather than carbonate.

The method 300 continues by LbL coating the CaCO₃ microparticles (operation 310). In operation 310, a polyelectrolyte multilayer (PEM) build-up may be employed by adsorbing five bilayers of negative PSS (poly(sodium 4-styrenesulfonate); Mw=70 kDa) and positive PAH (poly(allylamine hydrochloride); Mw=70 kDa) (2 mg/mL in 0.5 M NaCl) by using the layer-by-layer assembly protocol. For example, the CaCO₃ microparticles produced in operation 305 may be dispersed in a 0.5 M NaCl solution with 2 mg/mL PSS (i.e., polyanion) and shaken continuously for 10 min. The excess polyanion may be removed by centrifugation and washing with deionized water. Then, 1 mL of 0.5 M NaCl solution containing 2 mg/mL PAH (i.e., polycation) may be added and shaken continuously for 10 min. The excess polycation may be removed by centrifugation and washing with deionized water. This deposition process of oppositely charged polyelectrolyte may be repeated five times and, consequently, five PSS/PAH bilayers are deposited on the surface of the CaCO₃ microparticles. One of the resulting polymer coated CaCO₃ microparticles is shown at stage 308.

The thickness of this “inner shell” polyelectrolyte multilayer may be varied by changing the number of bilayers. Generally, it is desirable for the inner shell to change in permeability while the outer shell remains intact so that the reactants and the reaction products do not contaminate material into which the multi-compartment microcapsule may be dispersed. Typically, for a given shell diameter, thinner shells change in permeability more readily than thicker shells. Hence, in accordance with some embodiments of the present disclosure, the inner shell is made relatively thin compared to the outer shell. On the other hand, the inner shell must not be so thin as to change in permeability prematurely.

The PSS/PAH-multilayer in operation 310 is but one example of a polyelectrolyte multilayer. One skilled in the art will appreciate that other polyelectrolyte multilayers and other coatings may be used in lieu of, or in addition to, the PSS/PAH-multilayer in operation 310.

The method 300 continues by preparing ball-in-ball calcium carbonate microparticles in which Reactant 2 (which can be any suitable quencher, including methylene iodide) is immobilized by a second coprecipitation (operation 315). “Immobilize” means “removing from general circulation, for example by enclosing in a capsule.” The ball-in-ball CaCO₃ microparticles are characterized by a polyelectrolyte multilayer that is sandwiched between two calcium carbonate compartments. In operation 315, the polymer coated CaCO₃ microparticles may be resuspended in 1M CaCl₂ (0.615 mL), 1M Na₂CO₃ (0.615 mL), and deionized water (2.500 mL) containing methylene iodide (about 1 mg), rapidly mixed and thoroughly agitated on a magnetic stirrer for about 20 seconds at about room temperature. Amounts greater than 1 mg of methylene iodide may also be used. After the agitation, the precipitate may be separated from the supernatant by centrifugation and washed three times with water. The second coprecipitation is accompanied by formation of a coproduct, i.e., single core CaCO₃ microparticles that contain only methylene iodide in a suitable solvent. Hence, the resulting precipitate represents a mixture of ball-in-ball CaCO₃ microparticles and single core CaCO₃ microparticles. The ball-in-ball CaCO₃ microparticles, may be isolated by filtering off the solvent, optionally under a low vacuum. One of the resulting ball-in-ball CaCO₃ microparticles is shown at stage 312. Suitable solvents for the quencher during operation 315 include benzene, dimethylformamide (DMF), ethanol (EtOH), propylene carbonate, among others. An amount of solvent for the fluorophore is empirically determined by the amount of fluorophore used, for example, enough to at least partially solubilize the fluorophore.

The method 300 continues by LbL coating the ball-in-ball CaCO₃ microparticles (operation 320). In operation 320, a polyelectrolyte multilayer (PEM) build-up may be employed by adsorbing five bilayers of negative PSS (poly(sodium 4-styrenesulfonate); Mw=70 kDa) and positive PAH (poly(allylamine hydrochloride); Mw=70 kDa) (2 mg/mL in 0.5 M NaCl) by using the layer-by-layer assembly protocol. For example, the ball-in-ball CaCO₃ microparticles produced in operation 315 may be dispersed in a 0.5 M NaCl solution with 2 mg/mL PSS (i.e., polyanion) and shaken continuously for about 10 min. The excess polyanion may be removed by centrifugation and washing with deionized water. Then, 1 mL of 0.5 M NaCl solution containing 2 mg/mL PAH (i.e., polycation) may be added and shaken continuously for about 10 min. The excess polycation may be removed by centrifugation and washing with deionized water. This deposition process of oppositely charged polyelectrolyte may be repeated five times and, consequently, five PSS/PAH bilayers are deposited on the surface of the ball-in-ball CaCO₃ microparticles. One of the resulting polymer coated ball-in-ball CaCO₃ microparticles is shown at stage 314.

The thickness of this “outer shell” polyelectrolyte multilayer may be varied by changing the number of bilayers. Generally, it is desirable for the inner shell to change in permeability while the outer shell remains intact so that the reactants and the reaction products do not contaminate the material into which the multi-compartment microcapsule is dispersed. Typically, for a given shell diameter, thinner shells change in permeability more readily than thicker shells. Hence, in accordance with some embodiments of the present disclosure, the outer shell is made relatively thick compared to the inner shell.

The PSS/PAH-multilayer in operation 320, is but one example of a polyelectrolyte multilayer. One skilled in the art will appreciate that other polyelectrolyte multilayers and other coatings may be used in lieu of, or in addition to, the PSS/PAH-multilayer in operation 320. As noted above, coating polyelectrolyte multilayer capsules with lipids, for example, can result in a significant reduction of the capsule wall permeability.

In an embodiment, the outer shell wall material is made of a material for the fluorophore to escape the shell. In another embodiment, the outer shell wall material is made of a material where the photon yield outside the wall of the outer shell wall is maximized.

In an embodiment, the outer shell wall such that the % transmittance allows enough light to penetrate the shell to excite the fluorophore. In an embodiment, the outer shell wall has a transmittance of at least 75%. In certain embodiments, the outer shell wall material may include natural polymeric material, such as gelatin, arabic gum, shellac, lac, starch, dextrin, wax, rosin, sodium alginate, zein, and the like; semi-synthetic polymer material, such as methyl cellulose, ethyl cellulose, carboxymethyl cellulose, hydroxyethyl ethyl cellulose; full-synthetic polymer material, such as polyolefins, polystyrenes, polyethers, polyureas, polyethylene glycol, polyamide, polyurethane, polyacrylate, epoxy resins, among others. In certain embodiments, the method for wrapping a core material includes chemical methods such as interfacial polymerization, in situ polymerization, molecular encapsulation, radiation encapsulation; physicochemical methods such as aqueous phase separation, oil phase separation, capsule-heart exchange, pressing, piercing, powder bed method; and physical methods, such as spray drying, spray freezing, air suspension, vacuum evaporation deposition, complex coacervation, long and short centrifugation.

An example of a conventional technique of preparing the outer shell follows, and can be accomplished at stage 314. A gelatin is dissolved into n-hexane in a water bath at about 50° C. to obtain a 6% gelatin solution. The gelatin may optionally be swelled with deionized water before the preparation of the gelatin solution. The ball-in-ball CaCO₃ microparticles are added to the gelatin solution while stirring to form an emulsified dispersion system. The pH is then adjusted to about 3.5-3.8 using acetic acid, and then a 20% sodium sulfate solution is slowly added into the dispersion system while maintaining a temperature of about 50° C. The temperature of the dispersion system is then lowered to a temperature of about 15° C. The result is a colloid of gelatin coated ball-in-ball CaCO₃ microparticles.

Operation 325 is a CaCO₃ extraction. In operation 325, the CaCO₃ core of the ball-in-ball CaCO₃ microparticles may be removed by complexation with ethylenediaminetetraacetic acid (EDTA) (0.2 M, pH 7.5) leading to formation of shell-in-shell microcapsules. For example, the ball-in-ball CaCO₃ microparticles produced in operation 320 may be dispersed in 10 mL of the EDTA solution (0.2 M, pH 7.5) and shaken for about 4 h, followed by centrifugation and re-dispersion in fresh EDTA solution. This core-removing process may be repeated several times to completely remove the CaCO₃ core. The size of the resulting shell-in-shell microcapsules ranges from about 8 μm to about 10 μm and the inner core diameter is about 3 μm to about 5 μm. One of the resulting shell-in-shell microcapsules is shown at stage 316. Depending on the application of use, the shell-in-shell microcapsule can have a range of about 0.5 μm to about 200 μm.

As noted above, the fabrication of polyelectrolyte capsules in method 300 is based on the layer-by-layer (LbL) self-assembly of polyelectrolyte thin films. One skilled in the art will appreciate that a multi-compartment microcapsule for photon generation in accordance with some embodiments of the present disclosure may be produced by other conventional multi-compartment systems, such as polymeric micelles, hybrid polymer microspheres, and two-compartment vesicles.

As noted above, one skilled in the art will understand that various fluorophores and quenchers can be used. The chemistry used in fluorescence is a mature technology, and those skilled in the art will know that additional materials can be further added to the multi-compartment microcapsule. For example, enhancing reagents or blocking agents may be added to the reactants.

While method 300 illustrated formation of shell-in-shell microcapsules wherein the inner shell is adapted to change in permeability in response to a temperature change or range of temperature changes, the inner shell can be adapted to change in permeability in response to other forms of stimuli including magnetic field and ultrasound.

Other embodiments may utilize more than two reactants. For example, the multi-compartment microcapsule 100 of FIG. 1A may contain a plurality of inner microcapsules, such as 102, and the inner microcapsules may themselves contain other, inner, microcapsules. The various microcapsules may contain reactants and may change in permeability under compression to allow the reactants to come into contact. Similarly, the multi-compartment microcapsule 110 of FIG. 1B may contain a plurality of compartments formed by a plurality of membranes or barriers, such as 114, and the compartments may in turn contain one or more membranes or barriers, or may contain microcapsules. The various membranes or barriers may change in permeability under a temperature change or range of temperature changes to allow the reactants to come into contact. For example, one inner shell microcapsule contains reactants (A), and second inner microcapsule contains reactants (B), and the outer shell microcapsule contains reactants (C). Depending on the strength of the stimuli (i.e., temperature change), inner shell containing reactants (A) will change in permeability, while inner shell containing reactants (B) will not change in permeability.

Other embodiments may utilize more than one multi-compartment microcapsule, where the individual multi-compartment microcapsules have different strengths in response to heat or other stimuli (e.g., compressive force, a magnetic field, ultrasound, or combinations thereof). For example, one multi-compartment microcapsule may have an inner shell containing reactants (A), and the outer shell containing reactants (B). The other multi-compartment microcapsule may have an inner shell containing reactants (C) and the outer shell containing reactants (D). In this embodiment, multiple quenching reactions can be achieved depending on the strength of the applied stimulus. Quench 1 would comprise the quenching reaction of reactants (A) and (B) after a stimuli change the permeability of the inner shell of one microcapsule, while Quench 2 would comprise the quenching reaction of (C) and (D) after a stimuli changes the permeability of the inner shell of the other microcapsule.

In the embodiments described herein, one reactant set (i.e., Reactant 1) includes one or more fluorophores and optionally a solvent, while another reactant set (i.e., Reactant 2) includes one or more reactants, and optionally a solvent, being reactive with the fluorophores of the first reactant to change or eliminate the fluorescence thereof.

The reactants may be chosen to be inert with respect to the material of the microcapsule walls, or an isolating barrier within a microcapsule when the reactants are not in contact. The reactants also may be chosen to be inert with respect to the outer microcapsule wall when the reactants are in contact, or such that the chemical products of the reaction are inert with respect to the outer microcapsule wall, and any remnants of the inner microcapsule wall or barrier.

An amount of the first reactant and an amount of the second reactant may be determined. The amounts may be determined from the total amount of the reactants required to produce a desired amount of fluorescence, the ratio of each reactant according to a reaction equation, the desired dimensions of the microcapsule, and the manner of isolating the reactants within the capsule. For example, a microcapsule may be desired having a maximum dimension less than or equal to a desired final thickness of less than 0.5 microns, and the amount of reactants may be chosen corresponding to the volume available within a microcapsule formed according to that dimension.

One or more inner microcapsules, such as illustrated by microcapsule 102 of FIG. 1A, may be formed and the inner microcapsules may contain a first reactant(s) or a second reactant(s). In various embodiments, an inner microcapsule may be formed to contain a quencher (such as methylene iodide or nitromethane) optionally with a solvent or may be formed to contain fluorophores (including pyrenes, perenyl diimides, other reactants and solvents described herein, and combinations thereof). The inner microcapsule(s) may be formed with a capsule wall configured to change in permeability with application of a temperature change or range of temperature changes.

Further, an outer microcapsule may be formed containing the inner microcapsule(s) and one or more other reactants, in the manner of multi-compartment microcapsule 100 in FIG. 1A. The reactant(s) contained in the outer microcapsule may be inert with respect to each other and the microcapsule walls until in contact with one or more reactants contained in one or more inner microcapsules. In one embodiment, an outer microcapsule may contain a quencher (such as methylene iodide or nitromethane) optionally with a solvent, fluorophores (including pyrenes, perenyl diimides, other reactants and solvents described herein, and combinations thereof). In another embodiment, the outer microcapsule may contain fluorophores (including pyrenes, perenyl diimides, other reactants and solvents described herein, and combinations thereof), where one or more inner microcapsules may contain a quencher (such as methylene iodide or nitromethane) optionally with a solvent. The capsule wall of the outer microcapsule may be formed to not change in permeability at the temperature change or range of temperature changes applied to change in permeability the capsule wall of the inner microcapsule.

Alternatively, an embodiment may utilize a microcapsule having a structure as illustrated by multi-compartment microcapsule 110 in FIG. 1B. In accordance with this alternative embodiment an outer microcapsule may be formed having one or more inner barriers 114, which may be membranes, in the manner of multi-compartment microcapsule 110 in FIG. 1B, forming two (or more) compartments within the outer microcapsule. The particular reactants described above may be contained within the compartments, and the inner barrier(s) may be formed to change in permeability at a temperature change or range of temperature changes such as described above with respect to the capsule wall of an inner microcapsule.

These fluorescent microcapsules can be used to detect temperature thresholds in a wide variety of applications including soldering, adhesives, and compounding. Thus, the temperature applied to a fluorescent microcapsule may be within the range typical of that applied in the manufacture of circuit boards, adhesives, polymer, thermal interface materials, or any physical or chemical process in which microcapsules can be incorporated and which depends on achieving a certain temperature. For example, an adhesive that needs a certain temperature to adhere properly, or a polymer mixing or compounding process that needs to achieve a certain temperature.

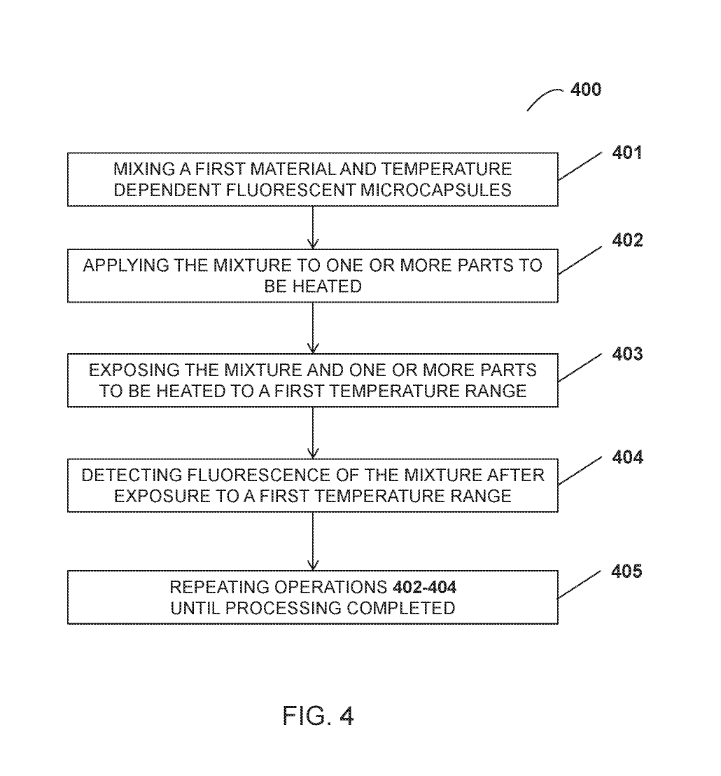

As shown in FIG. 4, a general method 400 of detecting a temperature threshold is provided. At operation 401, a first material and temperature dependent fluorescent microcapsules are mixed to form a mixture. The concentration of the microcapsules in the first material may be selected according to fluorophore, solvent, application and/or whether a fluorimeter is being used. At operation 402, the mixture is applied to one or more parts to be heated. The mixture and one or more parts to be heated is exposed to a first temperature range at operation 403. At operation 404, fluorescence of the mixture after exposure to a first temperature range can then be evaluated under the proper wavelength of light to check for fluorescence. For example, the parts can be evaluated for visible light change or by using a fluorimeter to detect fluorescence in the ultraviolet range. The method can further comprise repeating any of operations 402-404, including exposing the mixture and one or more parts to be heated to a second temperature range, wherein the second temperature range includes a temperature higher than any temperature in the first temperature range. These operations can be repeated until processing is deemed complete.

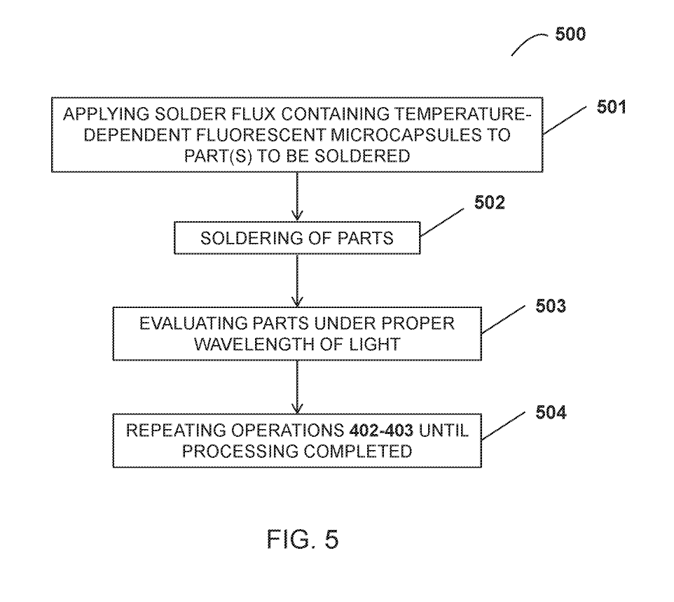

As an example, and referring to FIG. 5, a method to detect inactivated solder flux according to some embodiments is provided. The method 500 includes applying solder flux containing temperature dependent fluorescent microcapsules to part(s) to be soldered at operation 501. Such an operation may include physically mixing the fluorescent microcapsules with the solder flux. The flux may be any flux known in the art that is compatible with the microcapsules and the part(s) to be soldered. The concentration of the microcapsules with the solder flux may be between about 0.1 ppm and 1000 ppm per mass, between about 0.1 ppm and about 100 ppm, preferably between about 0.1 ppm and about 10 ppm. Mixing can be accomplished by, for example, mechanical means, by hand, by centrifuge, among others. In an embodiment, a known amount of flux and a known amount of microcapsules are weighed, the flux and microcapsules are mixed using a dispersion mixer at low speed or a tube roller, and then the mixture may be packaged in an appropriate container. At this stage, you can apply the mixture of microcapsules and flux to the part(s) to be soldered by any means, i.e., using a squirt bottle.

At operation 502, the parts undergo soldering. This operation may generally include attaching two members to using solder contacts, applying solder flux to a connection point, and applying a solder. This operation further includes exposing the solder flux and material to be soldered to a first temperature range. At operation 503, the parts are evaluated under the proper wavelength of light to check for fluorescence. For example, the parts can be evaluated for visible light change or by using a fluorimeter to detect fluorescence in the ultraviolet range. During the soldering operation, the components are heated to a desired activation temperature (for example, the SAC solder melting point is about 220° C.). When the temperature of the flux and the microcapsules reaches a desired temperature to inactivate the flux (i.e., a temperature or temperature range of about 85° C. to about 105° C.), the fluorescent molecules undergo a chemical reaction to render them non-fluorescent. This is achieved by the inner shell wall material melting, decomposing, or changing shape at the desired activation temperature. When the inner shell wall material undergoes such a response, the fluorescent molecules are exposed to a quencher reactant, rendering the microcapsules nonfluorescent. Operation 403 further includes inspecting the flux coated components after solder reflow, and identifying unactivated flux by inspecting the boards for fluorescence under a proper wavelength of light compatible with the fluorophore. If areas of the component/board fluoresce, a user can repeat operations 402-403 on areas where unactivated flux remains on the component, and reheating to drive off the remaining solvent carrier.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing is directed to embodiments of the present disclosure, other and further embodiments of the disclosure may be devised without departing from the basic scope thereof, and the scope thereof is determined by the claims that follow.

What is claimed is:

1. A multi-compartment microcapsule comprising:
a first compartment containing a fluorescent reactant;
a second compartment containing a reagent reactive with the fluorescent reactant; and
an isolating structure separating first and second compartments from each other and adapted to change in permeability in response to a stimulus, wherein the fluorescent reactant and reagent come in contact and react to decrease fluorescence when the isolating structure changes in permeability.

2. The multi-compartment microcapsule of claim 1, wherein the first compartment contains one or more fluorophores and the second compartment contains one or more quenching reactants.

3. The multi-compartment microcapsule of claim 2, wherein the one or more fluorophores is 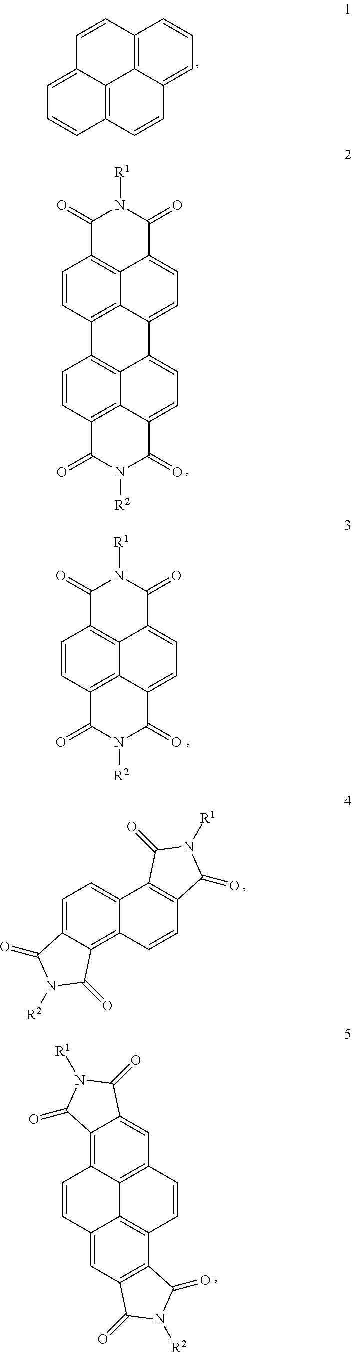 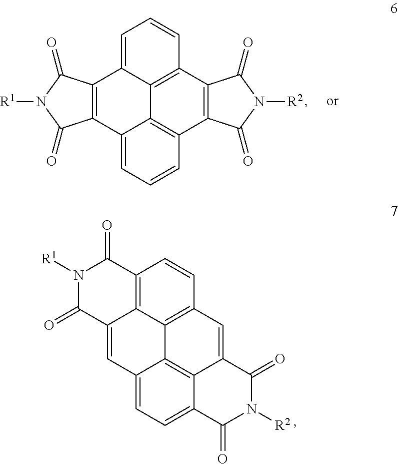
wherein R¹ and R² are each independently hydrogen or C₁ to C₄₀ branched or unbranched hydrocarbyl, C₁ to C₄₀ substituted or unsubstituted hydrocarbyl, C₁ to C₄₀ saturated or unsaturated hydrocarbyl, unsubstituted aryl, substituted aryl, unsubstituted heteroaryl, or substituted heteroaryl.

4. The multicompartment microcapsule of claim 2, wherein the one or more quenching reactants comprises methylene iodide, nitromethane, or a combination thereof.

5. The multicompartment microcapsule of claim 2, wherein the first compartment further contains water, ethanol, N,N-dimethylformamide (DMF), dimethyl sulfoxide (DMSO), and propylene carbonate, benzene, toluene, gamma butyrolactone, dimethyl imidazolidinone, tetraethylene glycol, or mixtures thereof.

6. The multi-compartment microcapsule of claim 1, wherein the multicompartment microcapsule is a shell-in-shell microcapsule comprising an inner shell contained within an outer shell, wherein the inner shell encapsulates the first compartment, wherein the outer shell encapsulates the second compartment, and wherein the inner shell defines the isolating structure.

7. The multi-compartment microcapsule of claim 6, wherein the inner shell and the outer shell are configured so that a stimulus changes the permeability of the inner shell while the outer shell remains intact.

8. The multi-compartment microcapsule of claim 7, wherein a given level of heat causes the inner shell to change in permeability while the outer shell remains intact.

9. The multi-compartment microcapsule of claim 6, wherein the outer shell comprises a polymer, and the outer shell has a transmittance of at least 75%.

10. The multi-compartment microcapsule of claim 9, wherein the polymer comprises gelatin, arabic gum, shellac, lac, starch, dextrin, wax, rosin, sodium alginate, zein, methyl cellulose, ethyl cellulose, carboxymethyl cellulose, hydroxyethyl ethyl cellulose, polyolefins, polystyrenes, polyethers, polyesters, polyureas, polyethylene glycol, polyamides, polyimides, urea-formaldehydes, polyurethane, polyacrylate, epoxy resins, and combinations thereof.

11. A method of making a solder flux containing multi-compartment microcapsules comprising:
preparing a microparticle containing a fluorescent reactant immobilized in a first sacrificial colloidal template;
coating a first polymer on a surface of the microparticle to form a polymer-coated microparticle;
preparing a ball-in-ball microparticle containing a reagent reactive with the fluorescent reactant, the reagent immobilized in a second sacrificial colloidal template, wherein the ball-in-ball microcapsule incorporates the polymer-coated microparticle;
coating a second polymer on a surface of the ball-in-ball microparticle to form a polymer-coated ball-in-ball microparticle; and
extracting the first and second colloidal templates from the polymer-coated ball-in-ball microparticle to form a shell-in-shell microcapsule having an inner shell and an outer shell, wherein the inner shell comprises the first polymer and contains the fluorescent reactant, wherein the outer shell corresponds to the second polymer and contains the quenching reagent, and wherein the fluorescent reactant and reagent are capable of reacting together to quench or partially quench fluorescence of the fluorescent reactant.

12. The method of claim 11, wherein the second polymer has a transmittance of at least 75%.

13. The method of claim 12, wherein the polymer comprises gelatin, arabic gum, shellac, lac, starch, dextrin, wax, rosin, sodium alginate, zein, methyl cellulose, ethyl cellulose, carboxymethyl cellulose, hydroxyethyl ethyl cellulose, polyolefins, polystyrenes, polyethers, polyesters, polyureas, polyethylene glycol, polyamides, polyimides, urea-formaldehydes, polyurethane, polyacrylate, epoxy resins, and combinations thereof.

14. The method of claim 11, wherein the inner shell further contains water, ethanol, N,N-dimethylformamide (DMF), dimethyl sulfoxide (DMSO), and propylene carbonate, benzene, toluene, gamma butyrolactone, dimethyl imidazolidinone, tetraethylene glycol, or mixtures thereof.

15. The method of claim 11, wherein the coating the first polymer on the surface of the microparticle to form a polymer-coated microcapsule includes embedding magnetic nanoparticles in the first polymer.

16. The method of claim 11, wherein the inner shell and the outer shell are configured so that a temperature change causes the inner shell to change in permeability while the outer shell remains intact.

17. The method of claim 11, further comprising mixing the shell in shell microcapsule with a solder flux material.

18. A method of detecting a temperature threshold, comprising:
mixing a first material and temperature dependent fluorescent microcapsules to form a mixture;
applying the mixture to one or more parts to be heated;
exposing the mixture and one or more parts to be heated to a first temperature range; and
detecting fluorescence of the mixture after exposure to a first temperature range.

19. The method of claim 18, further comprising exposing the mixture and one or more parts to be heated to a second temperature range, wherein the second temperature range includes a temperature higher than any temperature in the first temperature range.

20. The method of claim 18 wherein the first material comprises a solder flux.
